(19) United States
(12) Patent Application Publication
(10) Pub. No.: US 2014/0176192 A1
(43) Pub. Date: Jun. 26, 2014

(54) SEMICONDUCTOR DEVICE

(71) Applicant: SK HYNIX INC., Gyeonggi-do (KR)

(72) Inventor: Nak-Kyu PARK, Gyeonggi-do (KR)

(73) Assignee: SK HYNIX INC., Gyeonggi-do (KR)

(21) Appl. No.: 13/844,944

(22) Filed: Mar. 16, 2013

(30) Foreign Application Priority Data
Dec. 20, 2012 (KR) 10-2012-0149964

(51) Int. Cl. G01R 19/10

(52) U.S. Cl. CPC G01R 19/10
USPC 327/52

(57) ABSTRACT

A semiconductor device includes a differential input unit configured to generate internal differential signals based on external differential signals by using a first level voltage, a signal conversion unit configured to generate an internal synchronization signal based on the internal differential signals in response termination control signals by using a second level voltage, and a duty correction unit configured to correct duty of the internal synchronization signal by using the second level voltage.

### CROSS-REFERENCE TO RELATED APPLICATIONS

The present application claims priority of Korean Patent Application No. 10-2012-0149964, filed on Dec. 20, 2012, which is incorporated herein by reference in its entirety.

### BACKGROUND

1. Field

Exemplary embodiments of the present invention relate to semiconductor design technology, and more particularly, to a semiconductor device using differential signals.

2. Description of the Related Art

In general, a clock is a periodic pulse signal that toggles in a specific period and is used to determine a point of time at which a circuit or signal within a semiconductor device is activated in synchronization with a rising edge and a falling edge. Accordingly, a point of time at which the clock shifts may be relatively important, which has a great effect on reliability of the semiconductor device. A differential signaling method of sending a primary clock and a complementary clock having opposite logic levels to each other and receiving a signal by detecting a difference between voltage levels of the primary clock and the complementary clock, that is, differential clocks, is recently being used.

FIG. 1 shows a semiconductor device in accordance with the conventional art.

Referring to FIG. 1, the semiconductor device 100 includes a first differential input unit 110 for generating internal differential clocks OIN and OREF having lower voltage levels than a power supply voltage VDD based on external differential clocks CLK and CLKB, a second differential input unit 120 for generating an internal synchronization signal V2B having the lower voltage level than a power supply voltage VDD based on the internal differential clocks OIN and OREF, a first slope control unit 130 for primarily controlling duty of the internal synchronization signal V2B by using the power supply voltage VDD, and a second slope control unit 140 for secondarily controlling duty of an internal synchronization signal BUFOUT, primarily controlled by the first slope control unit 130, by using an internal voltage VPERI having a lower level than the power supply voltage VDD and for generating an internal clock INT_CLK based on a result of the controlled duty. Here, the internal voltage VPERI is generated within the semiconductor device 100. Furthermore, the external differential clocks CLK and CLKB have a predetermined swing width VID and differential input cross point voltage (hereinafter referred to as a ‘cross point voltage’) VIX, and the swing width VID and cross point voltage VIX of the external differential clocks CLK and CLKB are determined by taking the characteristics of the first differential input unit 110 into consideration. For example, the swing width VID of the external differential clocks CLK and CLKB may be defined between the power supply voltage VDD and a ground voltage VSS, and the cross point voltage VIX of the external differential clocks CLK and CLKB may be defined as a half voltage VDD/2 of the power supply voltage VDD. Each of the swing width INT_VID and the cross point voltage VIX of the internal differential clocks OIN and OREF is also defined between the power supply voltage VDD and the ground voltage VSS.

The first differential input unit 110 includes a 2 input-2 output differential amplifier. The second differential input unit 120 includes a 2 input-1 output differential amplifier. The first and the second differential input units 110 and 120 operate by using the power supply voltage VDD as a source voltage.

Furthermore, the first slope control unit 130 uses the power supply voltage VDD as a source voltage and includes a plurality of switching elements and a plurality of transistors in order to control the duty of the internal synchronization signal V2B. The second slope control unit 140 uses the internal voltage VPERI as a source voltage and includes a plurality of switching elements and a plurality of transistors in order to control the duty of the internal synchronization signal BUFOUT primarily controlled by the first slope control unit 130. The switching elements perform a switching operation in response to a control signal (not shown).

The operation of the semiconductor device 100 will be described with reference to FIG. 2. It is hereinafter assumed that the cross point voltage VIX of the external differential clocks CLK and CLKB is half voltage VDD/2 of the power supply voltage VDD.

FIG. 2 is a timing diagram illustrating the operation of the semiconductor device 100 in accordance with the conventional art.

Referring to FIG. 2, when the external differential clocks CLK and CLKB having a predetermined swing width VID and cross point voltage VIX (=VDD/2) are inputted to the internal synchronization signal generation unit 110, the internal synchronization signal generation unit 110 generates the internal synchronization signal V2B having a complementary metal-oxide semiconductor (CMOS) level which performs a pull swing between the power supply voltage VDD and the ground voltage VSS.

Next, the first slope control unit 130 primarily controls a slope of the internal synchronization signal V2B by using the power supply voltage VDD. The second slope control unit 140 secondarily controls a slope of the internal synchronization signal BUFOUT, primarily controlled by the first slope control unit 130, by using the internal voltage VPERI and finally outputs the internal clock INT_CLK based on a result of the secondarily controlled slope.

The semiconductor device 100 configured as above has the following concerns.

As can be seen from FIG. 2, the external differential clocks CLK and CLKB swing on the basis of half voltage VDD/2 of the power supply voltage VDD, and the internal clock INT_CLK swings on the basis of half voltage VPERI/2 of the internal voltage VPERI. That is, a common mode range of the external differential clocks CLK and CLKB corresponding to the cross point voltage VIX has a predetermined range A on the basis of the half voltage VDD/2 of the power supply voltage VDD, and a common mode range of the internal clock INT_CLK corresponding to the cross point voltage VIX has a predetermined range B on the basis of the half voltage VPERI/2 of the internal voltage VPERI. Here, the common mode range refers to a range in which the cross point voltage VIX of the differential clocks inputted for a stable operation of a receiver is specified in a specification. Accordingly, in order for the external differential clocks CLK and CLKB to be generated as the internal clock INT_CLK, switch to different voltage environments, that is, VDD->VPERI, may be desirable. Accordingly, there is a concern in that the internal clock INT_CLK may not be stably generated owing to a difference between voltage levels of the power supply voltage VDD and the internal voltage VPERI and the cross point voltage VIX between the external differential clocks CLK and CLKB and the internal clock INT_CLK.

Furthermore, since a plurality of the transistors is selectively driven by controlling a switching element when correcting duty, there may be a concern in that reliability may be low when correcting duty because the semiconductor device 100 may be sensitive to a change of a process, voltage, and temperature (PVT).

### SUMMARY

Various exemplary embodiments of the present invention are directed to providing a semiconductor device for stably generating an internal clock corresponding to external differential clocks in an environment in which an external power supply voltage and an internal voltage are mixed and used.

Another exemplary embodiment of the present invention is directed to providing a semiconductor device that is less sensitive to a change of a process, voltage, and temperature (PVT) when correcting duty.

In accordance with an embodiment of the present invention, a semiconductor device includes a differential input unit configured to generate internal differential signals based on external differential signals by using a first level voltage, a signal conversion unit configured to generate an internal synchronization signal based on the internal differential signals, in response termination control signals by using a second level voltage, and a duty correction unit configured to correct duty of the internal synchronization signal by using the second level voltage.

In accordance with another embodiment of the present invention, a semiconductor device includes a first differential amplification unit configured to generate internal differential signals by amplifying external differential signals, having a swing width and a differential input cross point voltage defined within a permitted limit of an external voltage, by using the external voltage, a control circuit unit configured to control a swing width and differential input cross point voltage of the internal differential signals within a permitted limit of an internal voltage, having a different voltage level from the external voltage, in response to first control signals, a second differential amplification unit configured to generate an internal synchronization signal by amplifying the internal differential signals, having the controlled swing width and differential input cross point voltage, by using the internal voltage, and a duty correction unit configured to correct duty of the internal synchronization signal by using the internal voltage.

In accordance with yet another embodiment of the present invention, a semiconductor device includes a first differential amplification unit coupled between a terminal for a power supply voltage and a terminal for a ground voltage and configured to generate internal differential clocks by amplifying external differential clocks, a first termination control unit coupled between a terminal for an internal voltage and the terminal for the ground voltage, coupled with a first output terminal for the internal differential clocks, and configured to control impedance incorporated into a first internal differential clock in response to first termination control signals, a second termination control unit coupled between the terminal for the internal voltage and the terminal for the ground voltage, coupled with a second output terminal for the internal differential clocks, and configured to control impedance incorporated into a second internal differential clock in response to second internal termination control signals, a second differential amplification unit coupled between the terminal for the internal voltage and the terminal for the ground voltage and configured to generate an internal synchronization signal by amplifying the internal differential clocks having the impedances controlled by the first and the second termination control units, and a duty correction unit coupled between the terminal for the internal voltage and the terminal for the ground voltage and configured to duty of the internal synchronization signal.

### BRIEF DESCRIPTION OF THE DRAWINGS

FIG. 1 is a diagram showing a semiconductor device in accordance with the conventional art.

FIG. 2 is a timing diagram illustrating the operation of the semiconductor device in accordance with the conventional art.

FIG. 3 is a block diagram of a semiconductor device in accordance with an exemplary embodiment of the present invention.

FIG. 4 is a detailed block diagram of a signal conversion unit shown in FIG. 3.

FIG. 5 is a circuit diagram of a first termination control unit shown in FIG. 4.

FIG. 6 is a circuit diagram of a duty correction unit shown in FIG. 3.

FIG. 7 is a timing diagram illustrating an operation of the semiconductor device in accordance with an exemplary embodiment of the present invention.

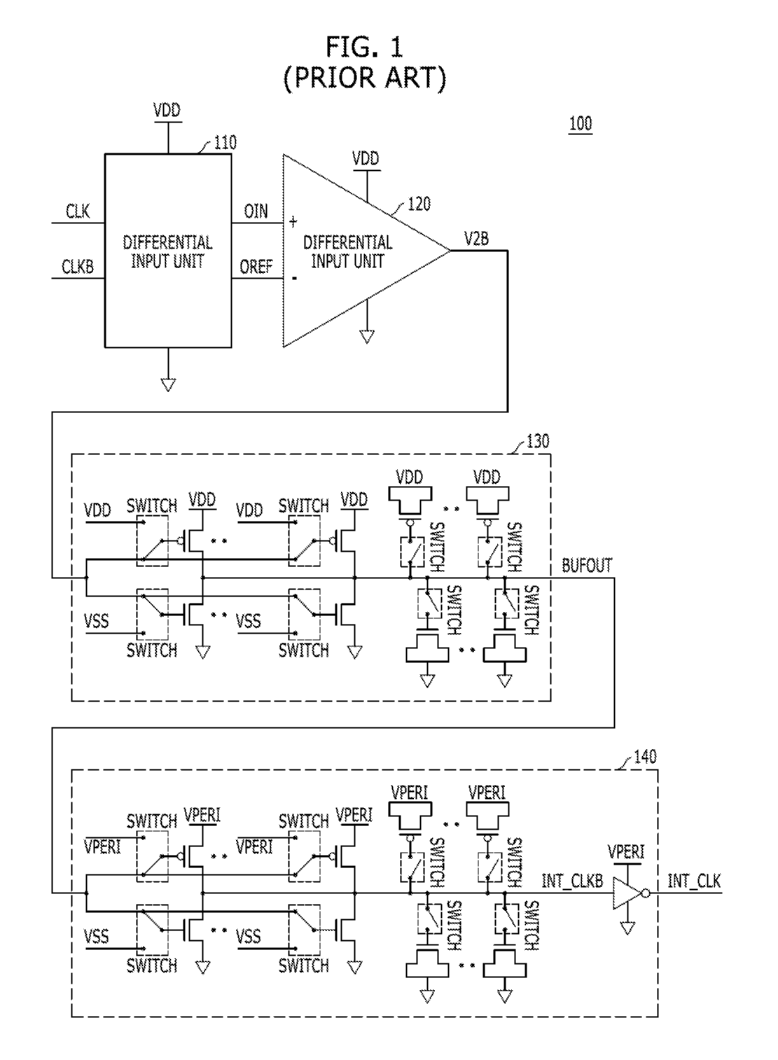

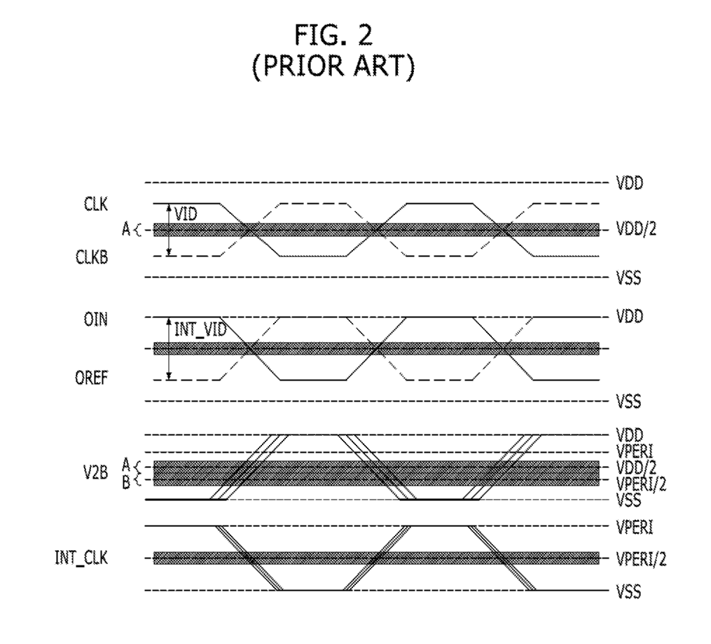

### DETAILED DESCRIPTION

Exemplary embodiments of the present invention will be described below in more detail with reference to the accompanying drawings. The present invention may, however, be embodied in different forms and should not be construed as being limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

In the present invention, the same reference numerals used in the prior art denote the same signals.

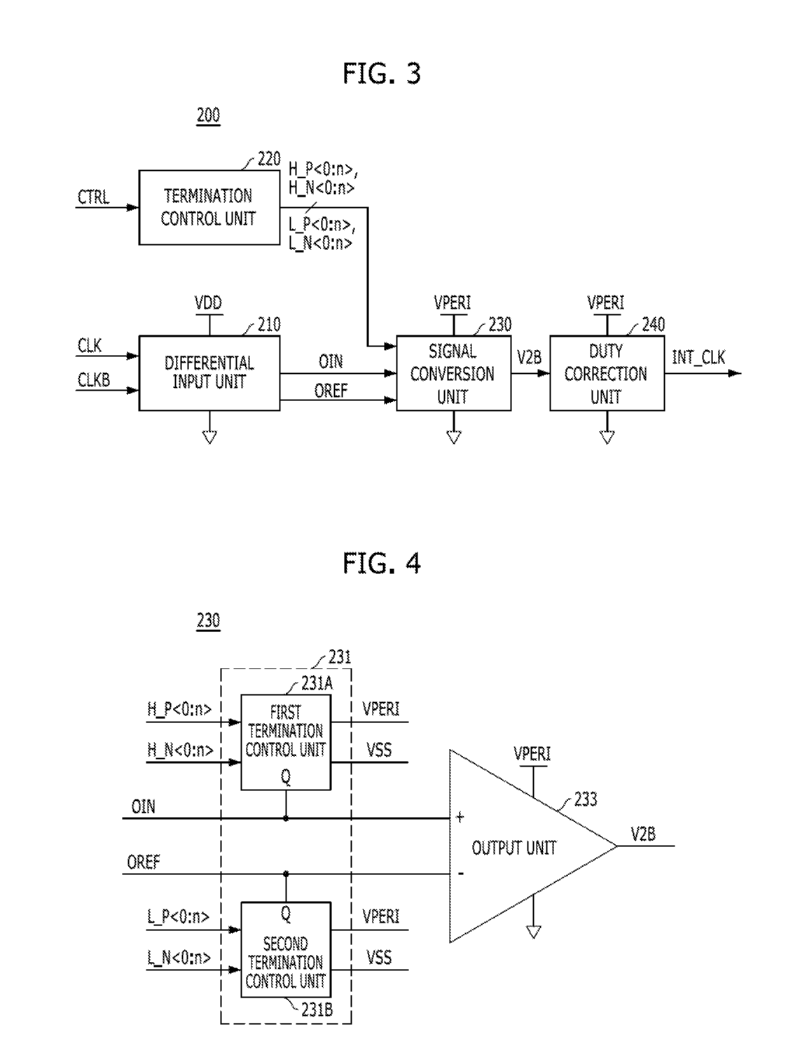

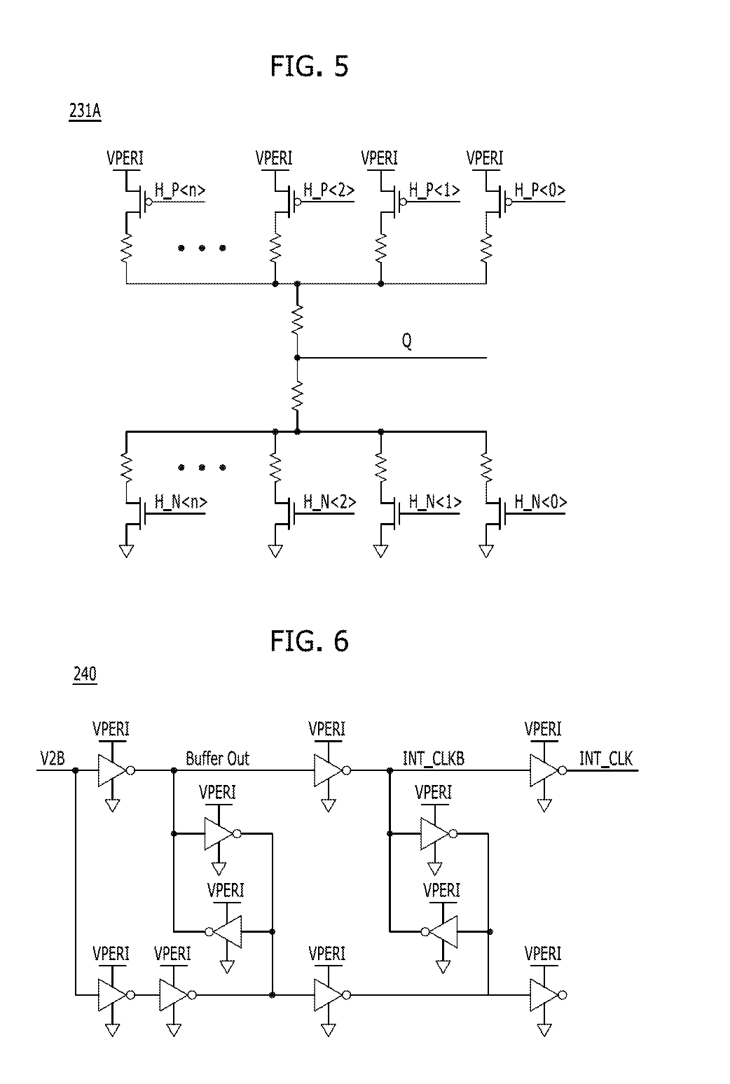

FIG. 3 is a block diagram of a semiconductor device in accordance with an exemplary embodiment of the present invention, FIG. 4 is a detailed block diagram of a signal conversion unit shown in FIG. 3, FIG. 5 is a circuit diagram of a first termination control unit shown in FIG. 4, and FIG. 6 is a circuit diagram of a duty correction unit shown in FIG. 3.

Referring to FIG. 3, a semiconductor device 200 includes a differential input unit 210 for generating internal primary and complementary differential docks OIN and OREF, corresponding to external differential clocks CLK and CLKB, by using an external power supply voltage VDD, a termination control unit 220 for generating first and second termination control signals H_P<0:n>, H_N<0:n> and L_P<0:n>, L_N<0:n> in response to a control signal CTRL, a signal conversion unit 230 for generating an internal synchronization signal V2B based on the internal primary and complementary differential clocks OIN and OREF, in response to the first and the second termination control signals H_P<0:n>, H_N<0:n> and L_P<0:n>, L_N<0:n> by using an internal voltage VPERI having a lower voltage level than the power supply voltage VDD, and a duty correction unit 240 for correcting duty of the internal synchronization signal V2B by using the internal voltage VPERI.

The differential input unit 210 include a 2 input-2 output differential amplifier coupled between a terminal for the power supply voltage VDD and a terminal for a ground voltage VSS and configured to generate the internal primary and complementary differential clocks OIN and OREF by amplifying the external differential clocks CLK and CLKB. Here, the external differential clocks CLK and CLKB may have a swing width VID and a cross point voltage VIX defined within a permitted limit of the power supply voltage VDD. For example, the swing width VID of the external differential docks CLK and CLKB may be defined between the power supply voltage VDD and the ground voltage VSS, and the cross point voltage VIX of the external differential clocks CLK and CLKB may be defined as half voltage VDD/2 of the power supply voltage VDD. The swing width VID and the cross point voltage VIX have been previously agreed between an external device (not shown) for supplying the external differential clocks CLK and CLKB and the differential input unit 210. The swing width VID and the cross point voltage VIX are defined within a range in which the differential input unit 210 may stably sense a transition point of the external differential clocks CLK and CLKB.

The termination control unit 220 may include an extended mode register set (EMRS), a decoder for test mode, and a fuse circuit. In this case, an EMRS coding signal, a test coding signal, and a fuse rupture enable signal may be used as the control signal CTRL.

As shown in FIG. 4, the signal conversion unit 230 includes a control circuit unit 231 for controlling the swing width INT_VID and the cross point voltage VIX of the internal primary and complementary differential clocks OIN and OREF within a permitted limit of the internal voltage VPERI in response to the first and the second termination control signals H_P<0:n>, H_N<0:n> and L_P<0:n>, L_N<0:n> and an output unit 233 for amplifying the internal primary and complementary differential clocks OIN and OREF, having the swing width INT_VID and the cross point voltage VIX controlled by the control circuit unit 231, by using the internal voltage VPERI and outputting the internal synchronization signal V2B of a complementary metal-oxide semiconductor (CMOS) level having the amplified clock. Here, the control circuit unit 231 includes a first termination control unit 231A and a second termination control unit 231B. The first termination control unit 231A is coupled between a terminal for the internal voltage VPERI and the terminal for the ground voltage VSS, coupled with an output terminal for the internal primary differential clock OIN, and configured to control impedance incorporated into the internal primary differential clock OIN in response to the first termination control signals H_P<0:n> and H_N<0:n>. The second termination control unit 231B is coupled between the terminal for the internal voltage VPERI and the terminal for the ground voltage VSS, coupled with the output terminal for the internal complementary differential clock OREF, and configured to control impedance incorporated into the internal complementary differential clock OREF in response to the second internal termination control signals L_P<0:n> and L_N<0:n>. The first and the second termination control units 231A and 231B may be designed identically, and thus only the first termination control unit 231A is described as an example. As shown in FIG. 5, the first termination control unit 231A may include transistors for pull-up and pull-down PMOS and NMOS configured to perform a switching operation in response to the first and the second termination control signals H_P<0:n>, H_N<0:n> and L_P<0:n>, L_N<0:n>, resistors disposed between the terminals for the power supply voltage VDD and the ground voltage VSS, and an output terminal Q. Referring back to FIG. 4, the output unit 233 includes a 2 input-1 output differential amplifier coupled between the terminal for the internal voltage VPERI and the terminal for the ground voltage VSS.

As shown in FIG. 6, the duty correction unit 240 may correct duty of the internal synchronization signal V2B in such a way as to mix the internal synchronization signal V2B and an inverted internal synchronization signal of the internal synchronization signal V2B. In other words, the duty correction unit 240 corrects duty of the internal synchronization signal V2B in such a way as to search for the middle of the difference between a pulse width of a logic high level and a pulse width of a logic low level based on the internal synchronization signal V2B and the inverted internal synchronization signal.

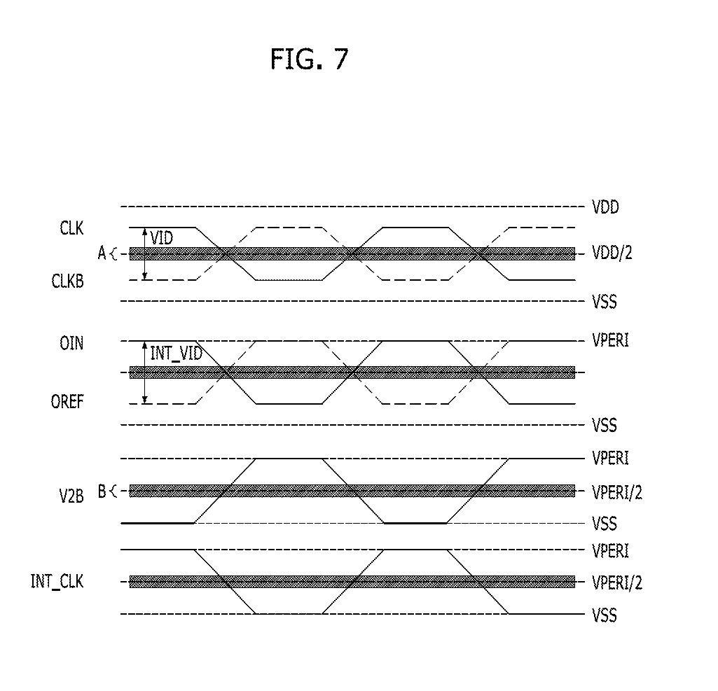

An operation of the semiconductor device 200 in accordance with an exemplary embodiment of the present invention is described below with reference to FIG. 7. It is hereinafter assumed that the cross point voltage VIX of the external differential clocks CLK and CLKB is half voltage VDD/2 of the power supply voltage VDD.

FIG. 7 is a timing diagram illustrating an operation of the semiconductor device 200 in accordance with an embodiment of the present invention.

Referring to FIG. 7, when the external differential clocks CLK and CLKB having a predetermined swing width VID and cross point voltage VIX (=VDD/2) are inputted to the differential input unit 210, the differential input unit 210 outputs the internal primary and complementary differential clocks OIN and OREF generated based on the external differential clocks CLK and CLKB, to the signal conversion unit 230.

In response thereto, the control circuit unit 231 of the signal conversion unit 230 controls the swing width VID and the cross point voltage VIX (=VDD/2) of the internal primary and complementary differential clocks OIN and OREF within a permitted limit of the internal voltage VPERI. That is, the internal primary and complementary differential clocks OIN and OREF controlled by the control circuit unit 231 swing between the internal voltage VPERI and the ground voltage VSS, and thus the internal primary and complementary differential clocks OIN and OREF are controlled so that they have a predetermined swing width INT_VIX and a predetermined cross point voltage VIX. Meanwhile, the operation of the control circuit unit 231 is described in more detail below. The first termination control unit 231A controls impedance, incorporated into the internal primary differential clock OIN of the internal primary and complementary differential clocks OIN and OREF, in response to the first termination control signals H_P<0:n> and H_N<0:n>, and the second termination control unit 231B controls impedance, incorporated into the internal complementary differential clock OREF of the internal primary and complementary differential docks OIN and OREF, in response to the second termination control signals L_P<0:n> and L_N<0:n>.

Next, the output unit 233 amplifies the internal primary and complementary differential clocks OIN and OREF and outputs the internal synchronization signal V2B of a complementary metal-oxide semiconductor (CMOS) level which has the amplified clocks and swings between the internal voltage VPERI and the ground voltage VSS.

Next, the duty correction unit 240 corrects duty of the internal synchronization signal V2B and finally outputs the internal clock INT_CLK based on a result of the correction.

In accordance with the embodiments of the present invention, there is an advantage in that the internal clock INT_CLK may be stably generated by generating the internal synchronization signal V2B of a complementary metal-oxide semiconductor (CMOS) level, having a swing width and cross point voltage VIX corresponding to a predetermined internal voltage VPERI, when a power supply voltage (VDD) environment is switched to an internal voltage (VPERI) environment. Furthermore, the present invention is advantageous in that the semiconductor device is less sensitive to a change of a process, voltage, and temperature (PVT) by correcting duty of the internal clock INT_CLK in such a way as to mix the internal synchronization signal V2B and an inverted internal synchronization signal.

There is an advantage in that the internal clock INT_CLK may be stably generated in an environment in which both of the external power supply voltage VDD and the internal voltage VPERI are used.

Furthermore, there is an advantage in that an internal clock may be stably generated by designing a semiconductor device so that a change of a process, voltage, and temperature (PVT) is minimized when correcting duty.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
a differential input unit configured to generate internal differential signals based on external differential signals by using a first level voltage;
a signal conversion unit configured to generate an internal synchronization signal based on the internal differential signals in response termination control signals by using a second level voltage; and
a duty correction unit configured to correct duty of the internal synchronization signal by using the second level voltage.

2. The semiconductor device of claim 1, wherein:
the first level voltage is an external voltage,
the second level voltage is an internally generated voltage, and
the first and the second level voltages have different voltage levels.

3. The semiconductor device of claim 1, wherein the external differential signals have a swing width and a differential input cross point voltage defined within a permitted limit of the first level voltage.

4. The semiconductor device of claim 1, wherein the internal synchronization signal has a swing width and a differential input cross point voltage defined within a permitted limit of the second level voltage.

5. The semiconductor device of claim 1, further comprising a termination control unit configured to generate the termination control signals in response to a control signal,
wherein the termination control unit comprises any one of an extended mode register set (EMRS), a decoder for test mode, and a fuse circuit.

6. The semiconductor device of claim 1, wherein the duty correction unit is configured to correct the duty of the internal synchronization signal by mixing the internal synchronization signal and an inverted internal synchronization signal of the internal synchronization signal.

7. A semiconductor device, comprising:
a first differential amplification unit configured to generate internal differential signals by amplifying external differential signals, having a swing width and a differential input cross point voltage defined within a permitted limit of an external voltage, by using the external voltage;
a control circuit unit configured to control a swing width and differential input cross point voltage of the internal differential signals within a permitted limit of an internal voltage, having a different voltage level from the external voltage, in response to first control signals;
a second differential amplification unit configured to generate an internal synchronization signal by amplifying the internal differential signals, having the controlled swing width and differential input cross point voltage, by using the internal voltage; and
a duty correction unit configured to correct duty of the internal synchronization signal by using the internal voltage.

8. The semiconductor device of claim 7, wherein the control circuit unit controls impedance incorporated into the internal differential signals.

9. The semiconductor device of claim 7, further comprising a control signal generation unit configured to generate the control signals in response to a second control signal,
wherein the control signal generation unit comprises any one of an extended mode register set (EMRS), a decoder for test mode, and a fuse circuit.

10. The semiconductor device of claim 7, wherein the duty correction unit corrects the duty of the internal synchronization signal by mixing the internal synchronization signal and an inverted internal synchronization signal of the internal synchronization signal.

11. The semiconductor device of claim 8, further comprising a control signal generation unit configured to generate second control signals in response to a second control signal,
wherein the control signal generation unit comprises any one of an extended mode register set (EMRS), a decoder for test mode, and a fuse circuit.

12. The semiconductor device of claim 8, wherein the duty correction unit corrects the duty of the internal synchronization signal by mixing the internal synchronization signal and an inverted internal synchronization signal of the internal synchronization signal.

13. A semiconductor device, comprising:
a first differential amplification unit coupled between a terminal for a power supply voltage and a terminal for a ground voltage and configured to generate internal differential clocks by amplifying external differential clocks;
a first termination control unit coupled between a terminal for an internal voltage and the terminal for the ground voltage, coupled with a first output terminal for the internal differential clocks, and configured to control impedance incorporated into a first internal differential clock in response to first termination control signals;
a second termination control unit coupled between the terminal for the internal voltage and the terminal for the ground voltage, coupled with a second output terminal for the internal differential clocks, and configured to control impedance incorporated into a second internal differential clock in response to second internal termination control signals;
a second differential amplification unit coupled between the terminal for the internal voltage and the terminal for the ground voltage and configured to generate an internal synchronization signal by amplifying the internal differential clocks having the impedances controlled by the first and the second termination control units; and
a duty correction unit coupled between the terminal for the internal voltage and the terminal for the ground voltage and configured to duty of the internal synchronization signal.

14. The semiconductor device of claim 13, wherein:
the external differential clocks have a swing width and a differential input cross point voltage defined between a level of the power supply voltage and a level of the ground voltage,
the internal differential clocks have a swing width and a differential input cross point voltage defined between a level of the internal voltage and the level of the ground voltage, and
the internal synchronization signal performs a pull swing between the level of the internal voltage and the level of the ground voltage and has a differential input cross point voltage corresponding to half the level of the internal voltage.

15. The semiconductor device of claim 13, further comprising a control signal generation unit configured to generate the first and the second termination control signals in response to a control signal,
wherein the control signal generation unit comprises any one of an extended mode register set (EMRS), a decoder for test mode, and a fuse circuit.

16. The semiconductor device of claim 13, wherein the duty correction unit corrects the duty of the internal synchronization signal by mixing the internal synchronization signal and an inverted internal synchronization signal of the internal synchronization signal.

17. The semiconductor device of claim 14, further comprising a control signal generation unit configured to generate the first and the second termination control signals in response to a control signal,
wherein the control signal generation unit comprises any one of an extended mode register set (EMRS), a decoder for test mode, and a fuse circuit.

18. The semiconductor device of claim 14, wherein the duty correction unit corrects the duty of the internal synchronization signal by mixing the internal synchronization signal and an inverted internal synchronization signal of the internal synchronization signal.
